(19) United States
(12) Patent Application Publication
(10) Pub. No.: US 2026/0317907 A1
(43) Pub. Date: Oct. 15, 2026

(54) HEATING APPARATUS HAVING ELECTROSTATIC ATTRACTION FUNCTION

(71) Applicant: Shin-Etsu Chemical Co., Ltd., Tokyo (JP)

(72) Inventors: Akihiro HIRATE, Gunmaken (JP); Shoji KANO, Gunmaken (JP); Waichi YAMAMURA, Gunmaken (JP); Naoya MIYAJIMA, Gunmaken (JP)

(73) Assignee: Shin-Etsu Chemical Co., Ltd., Tokyo (JP)

(21) Appl. No.: 19/246,966

(22) Filed: Jun. 24, 2025

(30) Foreign Application Priority Data
Apr. 15, 2025 (JP) 2025-66716

(51) Int. Cl. C23C 16/458; H05B 3/00; H05B 3/03; H05B 3/06; H05B 3/14

(52) U.S. Cl. CPC C23C 16/4586; H05B 3/0019; H05B 3/03; H05B 3/06; H05B 3/145

(57) ABSTRACT

Provided is a heating apparatus having electrostatic attraction function capable of improving temperature distribution of a wafer. Provided is a heating apparatus having electrostatic attraction function 1, comprising at least a supporting substrate 2, an electrode for electrostatic attraction 4 and a heating layer 5 formed on the supporting substrate 2, an insulator layer 3 containing boron nitride formed on the electrode for electrostatic attraction 4 and the heating layer 5, and a power supply terminal portion 7 for supplying electricity to the heating layer 5, wherein the power supply terminal portion 7 has a structure having no through hole communicating with a wafer-mounting surface, and the power supply terminal portion 7 is provided with a hollow portion 9 for enabling positioning.

### FIELD OF THE INVENTION

The present invention relates to a heating apparatus having electrostatic attraction function, and specifically relates to a heating apparatus having electrostatic attraction function, which is preferably used for a heating process of a semiconductor wafer during a semiconductor device fabrication process including a temperature rising step.

### TECHNICAL BACKGROUND OF THE INVENTION

In a recent fabrication process of semiconductor devices, a heating apparatus having electrostatic attraction function is used for supporting a wafer by electrostatic attraction in molecular-beam epitaxy and CVD, sputtering, etching, ion implantation, and the like. The material of such a heating apparatus having electrostatic attraction function is shifted from resin to ceramics as the temperature used for the process increases (see IP Publication 1 and IP Publication 2). In a high temperature process performed at 200 °C or higher, a wafer heating apparatus with integrated ceramics using a ceramic thin film as a heating layer is used (see IP Publication 3).

Examples of the heating apparatus having electrostatic attraction function used in such a high temperature process include an electrostatic chuck formed with pyrolytic boron nitride and pyrolytic carbon. This heating apparatus is an integrated resistance heating-type heating apparatus with multilayered structure having electrostatic attraction function, in which the heating apparatus includes a (supporting) substrate formed of carbon or a carbon composite material, an insulating layer formed of pyrolytic boron nitride (hereinafter sometimes referred to as “PBN”) formed on the (supporting) substrate by a thermal chemical vapor deposition method (thermal CVD method), a heater patterned electrically conductive layer formed of pyrolytic graphite deposited on and adhered to the insulating layer by a thermal CVD method, and fine-layered protective films of, for example, pyrolytic boron nitride which covers the heater pattern (see IP Publication 4 and IP Publication 5).

Such a resistance heating-type heating apparatus having electrostatic attraction function provides high purity, and is chemically stable and highly resistant to thermal shock, and thus used in various fields that require rapid rise and rapid drop in temperature.

For example, it is used in the field of semiconductor wafer fabrication, specifically, in a process of treating a semiconductor wafer and the like one by one by single wafer processing at gradually changing temperatures.

The heating apparatus having electrostatic attraction function with multilayered structure has an insulating layer to which a wafer is mounted, in which temperature dependency of the resistivity of the insulating layer is low, and thus has an advantage of availability of Johnsen-Rahbek force within a wide temperature range from room temperature to 700 °C, and have found wide applications in semiconductor fabrication processes.

Conventionally, in the heating apparatus having electrostatic attraction function including pyrolytic boron nitride, a wire for power supply (power source wire) is fixed to a power supply terminal portion for supplying electricity to a heating layer with a bolt and a nut. Unfortunately, in this method, since the bolt is not in contact with a wafer, a gap is formed between the bolt and the wafer, which causes a decrease in temperature.

### PRIOR ART PUBLICATIONS

### Publications

IP Publication 1: Japanese Patent Application Publication No. S52-067353

IP Publication 2: Japanese Patent Application Publication No. S59-124140

IP Publication 3: Japanese Patent Application Publication No. H04-124076

IP Publication 4: Japanese Patent Application Publication No. H05-129210

IP Publication 5: Japanese Patent Application Publication No. H07-010665

### SUMMARY OF THE INVENTION

### Problems the Invention Seeks to Solve

Recently, in high temperature processes performed at 200 °C or higher in semiconductor device fabrication processes, improvement in temperature uniformity is required. A major factor of the decrease in temperature uniformity is the presence of portions where the wafer and the wafer-mounting surface of the heating apparatus are not in contact with each other, specifically, the presence of a hole portion of a through hole provided through the wafer-mounting surface and an outermost peripheral portion of the wafer-mounting surface which are not in contact with the wafer. When the wafer and the wafer-mounting surface are not in contact with each other, heat escapes from the gaps and the temperature of the wafer decreases.

### Means to Solve the Problems

The present inventors have carried out investigations on factors causing the decrease in temperature of the wafer-mounting surface. As a result, the present inventors have found that sparks caused by misalignment between a power source wire and a power supply terminal portion can be avoided by a structure which has no through hole communicating with the wafer-mounting surface in a power supply terminal portion for supplying electricity to a heating layer, and which has a hollow portion for enabling positioning formed in the power supply terminal portion. Consequently, the present inventors have found that the problems can be solved by the following structures. The present invention is as follows.

[1] A heating apparatus having electrostatic attraction function, comprising:
at least a supporting substrate;
an electrode for electrostatic attraction and a heating layer formed on the supporting substrate;
an insulator layer containing boron nitride formed on the electrode for electrostatic attraction and the heating layer; and
a power supply terminal portion for supplying electricity to the heating layer,
wherein the power supply terminal portion has a structure having no through hole communicating with a wafer-mounting surface, and
a power source wire is fixed to the power supply terminal portion with a spring terminal.

[2] The heating apparatus having electrostatic attraction function according to [1], wherein the power supply terminal portion is provided with a hollow portion for enabling positioning of the spring terminal.

[3] The heating apparatus having electrostatic attraction function according to [2], wherein a ratio of an outer diameter D1/a height h1 of the hollow portion is 0.1 or more and 10 or less.

[4] The heating apparatus having electrostatic attraction function according to [2] or [3], wherein the heating layer in the hollow portion is removed.

[5] The heating apparatus having electrostatic attraction function according to any one of [2] to [4], wherein a ratio of an outer diameter D2 of the exposed portion of the power supply terminal portion to an outer diameter D1 of the hollow portion as the ratio of the outer diameters (D 2/D1) is 1.2 or more and 100 or less.

[6] The heating apparatus having electrostatic attraction function according to any one of [1] to [5], wherein the power source wire is fixed to the power supply terminal portion by inserting a washer with plasticity between the power supply terminal portion and the spring terminal.

[7] The heating apparatus having electrostatic attraction function according to any one of [1] to [6], wherein
in the insulator layer formed on the electrode for electrostatic attraction, a ratio of a surface resistivity (ρsE) of a portion facing the electrode for electrostatic attraction to a surface resistivity (ρsS) of a portion facing an attracted material (ρsE/ρsS) is more than 1 and 100 or less, ρsE and ρsS are each 1×10⁸ Ω/□ or more, and a surface resistivity of an intermediate portion is 2×10⁸ to 9×10¹⁴ Ω/□, and wherein the insulator layer has a thickness of 50 to 300 μm.

[8] The heating apparatus having electrostatic attraction function according to any one of [1] to [7], wherein
in the insulator layer formed on the electrode for electrostatic attraction, when a surface resistivity (Ω/□) in a lateral direction of the insulator layer is denoted by A and a volume resistivity (Ω·cm) in a depth direction of the insulator layer is denoted by B, a ratio of a surface resistivity to a volume resistivity (A/B) is 0.01 or more and 10,000 or less, and a volume resistivity in the depth direction of the insulator layer is 10⁶ to 10¹⁵ Ω·cm.

[9] The heating apparatus having electrostatic attraction function according to any one of [1] to [8], wherein
the electrode for electrostatic attraction and/or the heating layer are formed of pyrolytic graphite containing boron and/or boron carbide in an amount of from 0.001 to 30 mass % as a boron concentration.

[10] The heating apparatus having electrostatic attraction function according to any one of [1] to [9], wherein the electrode for electrostatic attraction and/or the heating layer are formed such that a protective layer formed on the supporting substrate is sandwiched therebetween.

[11] The heating apparatus having electrostatic attraction function according to [10], wherein the protective layer includes any one of silicon nitride, boron nitride, aluminum nitride, and pyrolytic boron nitride.

[12] The heating apparatus having electrostatic attraction function according to any one of [1] to [11], wherein
the supporting substrate includes any one of silicon nitride sintered body, boron nitride sintered body, mixed sintered body of boron nitride and aluminum nitride, alumina sintered body, aluminum nitride sintered body, pyrolytic boron nitride, and pyrolytic boron nitride-coated graphite as a main component.

[13] The heating apparatus having electrostatic attraction function according to any one of [1] to [12], wherein the insulator layer is formed such that a resistivity of the insulator layer is gradually altered in the depth direction by a chemical vapor deposition method.

### Effects of the Invention

The present invention provides a structure having no through hole communicating with a wafer-mounting surface in a power supply terminal portion for supplying electricity to a heating layer. That is, the structure has no through hole which causes a decrease in temperature of a wafer, resulting in a larger area that is in contact with the wafer. As a result, the temperature uniformity of the wafer-mounting surface is improved, and the temperature distribution of the wafer becomes more favorable. Furthermore, the power supply terminal portion has a structure having a hollow portion for enabling positioning of a spring terminal, in which the spring terminal is pressed against the hollow portion. Thus, the present invention can provide a heating apparatus having electrostatic attraction function that further improves the temperature uniformity of the wafer-mounting surface. Accordingly, in a device fabrication process or the like, when such a heating apparatus is used for heating a wafer, the yield of devices is improved, and it can be steadily used for a long term.

### BRIEF DESCRIPTION OF DRAWINGS

FIG. 1 is a schematic diagram of a heating apparatus having electrostatic attraction function produced in Example 1.

FIG. 2 is a schematic diagram of a heating apparatus having electrostatic attraction function produced in Comparative Example 1.

FIG. 3 is an explanatory plan view for describing an outer diameter D1 of a hollow portion 9 and an outer diameter D2 of an exposed portion of a power supply terminal portion.

FIG. 4 is an explanatory cross-sectional view for describing a portion facing an electrode for electrostatic attraction and a portion facing an attracted material in an insulator layer.

### EXAMPLES TO EMBODY THE INVENTION

Hereinafter, the embodiments of the present invention will be described in detail with reference to figures, but the present invention is not limited thereto. In all figures, the same or corresponding portions are denoted by the same sign.

The heating apparatus according to the present invention is a heating apparatus having electrostatic attraction function for holding and fixing a semiconductor wafer, which is an object to be heated, while heating is performed. The heating apparatus according to the present invention is used in a CVD system and a sputtering apparatus, or an etching machine for etching a produced thin film, which are used in a semiconductor device fabrication process.

A heating apparatus 1 according to the present invention comprises at least a supporting substrate 2, an electrode for electrostatic attraction 4 and a heating layer 5 formed on the supporting substrate, an insulator layer 3 formed on the electrode for electrostatic attraction and the heating layer, and a power supply terminal portion 7 for supplying electricity to the heating layer, has electrostatic attraction function, and is characterized by a structure having no through hole 11 communicating with a wafer-mounting surface in the power supply terminal portion 7 for supplying electricity to the heating layer 5. Furthermore, the heating apparatus 1 according to the present invention is also characterized by a structure having a hollow portion 9 for enabling positioning of a spring terminal 8 (hereinafter, sometimes simply referred to as “a hollow portion for enabling positioning” or “a hollow portion”) in the power supply terminal portion 7 for supplying electricity to the heating layer 5, wherein a protruding portion (tip) of the spring terminal 8 is inserted into the hollow portion 9, and the spring terminal 8 is configured to press a power source wire against the power supply terminal portion 7 to fix the power source wire.

The power supply terminal portion 7 refers to a portion with which a terminal (power source wire) for supplying electricity to the heating layer 5 comes into contact, and which has an exposed portion where a part of the heating layer 5 is not covered with the insulator layer 3. In the prior art, the power source wire is fixed to the power supply terminal portion 7 with a bolt 12 and a nut 13.

The hollow portion 9 for enabling positioning refers to a depressed portion provided in the power supply terminal portion 7, and is used for enabling precise positioning of the spring terminal 8 for pressing the power source wire against the power supply terminal portion 7 to fix the power source wire. Thus, the hollow portion 9 secures the position of the power supply terminal portion 7 to which the power source wire is connected, resulting in an improved electrical contact.

The through hole 11 refers to a hole provided in the prior art for allowing a bolt 12 for fixing the power source wire to the power supply terminal portion 7 to be inserted into the hole, for supplying electricity to the heating layer 5, and for fixing the power supply terminal portion 7. The present invention provides a structure having no through hole 11.

### Heating Apparatus Having Electrostatic Attraction Function

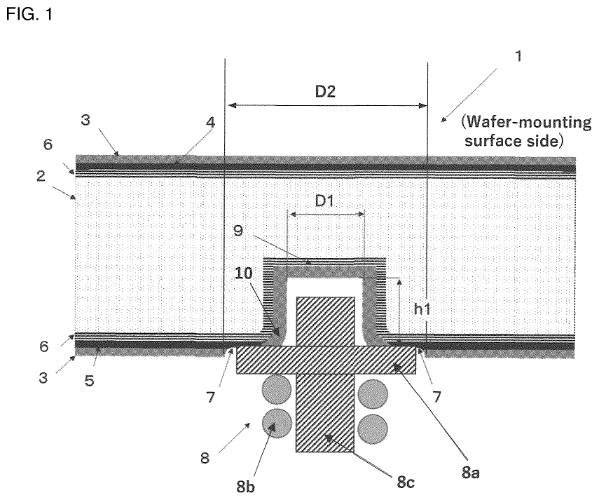

FIG. 1 shows an example of the heating apparatus having electrostatic attraction function according to the present invention. In the heating apparatus having electrostatic attraction function (hereinafter, sometimes simply referred to as “heating apparatus”) 1, an electrode for electrostatic attraction 4 and a heating layer 5 are formed such that a protective layer 6 formed on a disk-shaped supporting substrate 2 is sandwiched therebetween, and an insulator layer 3 is formed on the electrode for electrostatic attraction 4 and the heating layer 5. The electrode for electrostatic attraction 4 is formed on a wafer-mounting surface side of the supporting substrate 2, and the heating layer 5 is formed on the other side of the supporting substrate 2, that is, on a side opposite to the wafer-mounting surface side. On the heating layer 5 side of the supporting substrate 2, at least one power supply terminal portion 7 and its hollow portion 9 are provided. The depth of the hollow portion 9 reaches the middle of the supporting substrate 2, but the hollow portion 9 does not penetrate the supporting substrate 2 to communicate with the wafer-mounting surface. The insulator layer 3 on the heating layer 5 is removed such that the removed portion surrounds the hollow portion 9. The region around the hollow portion 9 where the heating layer 5 is exposed acts as a terminal portion (terminal portion which comes into contact with a power source wire) of the power supply terminal portion 7 for supplying electricity from a spring terminal 8 to the heating layer 5.

In the case of heating a semiconductor wafer, the wafer is attracted to and fixed on the insulator layer 3 disposed on the front side of the supporting substrate 2 by the electrode for electrostatic attraction 4, and heated by the electrically conductive heating layer 5 disposed on the back side of the supporting substrate 2.

In a conventional heating apparatus, a wire for power supply is fixed to a power supply terminal portion 7 for supplying electricity to a heating layer 5 by a method using a bolt 12 and a nut 13. In this case, the bolt 12 does not come into contact with a wafer, and a gap is formed between the bolt 12 and the wafer, which causes a decrease in temperature.

On the other hand, the heating apparatus according to the present invention has a structure having no through hole communicating with the wafer-mounting surface in the power supply terminal portion 7 for supplying electricity to the heating layer 5. Furthermore, the power supply terminal portion 7 has a hollow portion 9 for enabling positioning of a spring terminal. The power supply terminal 7 has a structure in which a spring terminal 8 having a protruding tip is inserted into the hollow portion 9, and a power source wire is pressed against the power supply terminal portion 7. This structure reduces the possibility of misalignment of the spring terminal 8, and thus sparks caused by the misalignment is avoided (FIG. 1).

Hereinafter, each component of the heating apparatus 1 according to the present invention will be specifically described.

### Supporting Substrate

Although the material contained in the supporting substrate 2 is not particularly limited, it is preferred that the supporting substrate 2 is composed of any one of silicon nitride sintered body, boron nitride sintered body, mixed sintered body of boron nitride and aluminum nitride, alumina sintered body, aluminum nitride sintered body, and graphite. These materials are desired because the physical properties are stable even in a medium to high temperature range from 500 to 800 °C. In particular, graphite is desired because it is stable at a high temperature up to 2000 °C or higher.

Examples of the shape of the supporting substrate 2 include, but are not particularly limited to, a disk shape, a cylindrical shape, a disk or cylindrical shape with protrusions or hollows, or the like.

### Protective Layer

The protective layer 6 formed on the supporting substrate 2 prevents negative effects due to impurities, gas, and the like contained in the supporting substrate 2 on a subsequent fabrication process. Such a protective layer 6 is necessary to ensure insulation properties and is also required to prevent oxidation when the supporting substrate 2 is composed of, for example, graphite.

On the other hand, when the supporting substrate 2 is an insulating material, the protective layer 6 is not necessary. However, the protective layer 6 is preferably provided because the protective layer 6 can prevent contamination with impurities and the like as described above.

It is preferred that the material of the protective layer 6 is stable up to a high temperature, and examples of the material include silicon nitride, boron nitride, pyrolytic boron nitride, and aluminum nitride.

With respect to the thickness of the protective layer 6, if the layer is too thick, the layer can be easily detached due to a difference in the thermal expansion between the layer and the supporting substrate. If the layer is too thin, impurities, gases, and the like may pass through pinholes of the layer, causing negative effects on a subsequent fabrication process. Accordingly, the thickness of the protective layer 6 is preferably within a range from 10 to 500 μm, and particularly desirably from 30 to 300 μm.

### Electrode for Electrostatic Attraction and Heating Layer

The electrode for electrostatic attraction 4 and the heating layer 5 are formed such that a protective layer 6 formed on the supporting substrate 2 is sandwiched therebetween. With respect to the material, the electrode for electrostatic attraction 4 and the heating layer 5 are preferably formed of pyrolytic graphite containing boron and/or boron carbide in an amount of from 0.001 to 30 mass % as a boron concentration. The electrode for electrostatic attraction 4 and the heating layer 5 formed as described above have a stronger anchor effect. Therefore, the insulator layer 3 formed on the electrode for electrostatic attraction 4 and the heating layer 5 favorably adheres and is bonded to the electrode for electrostatic attraction 4 and the heating layer 5, and detachment of the insulator layer 3 can be prevented even after repeated rise and drop in temperature.

The pyrolytic graphite containing boron and/or boron carbide in an amount within the above range has a property that reduces the temperature dependency of resistivity. Thus, there is another advantage that temperature controllability is improved by using such a material for the heating layer 5, that is, the temperature distribution of the wafer is improved, a high thermal shock resistance is achieved, and the possibility of detachment of the insulator layer 3 is reduced even after repeated rise and drop in temperature. Furthermore, a heating apparatus having electrostatic attraction function 1 which has suitable electrical resistance and sufficient electrostatic attraction force even in a medium to high temperature range from 500 to 800 °C, and which can be steadily used even with rapid rise and drop in temperature can be provided, in which breakage of devices due to leakage current is prevented and dielectric breakdown does not occur. When the boron concentration is 0.001 mass % or more, a sufficient anchor effect can be achieved. On the other hand, when the boron concentration is 30 mass % or less, excessive grain growth does not occur, sufficient film growth is achieved, and the functions as the electrode for electrostatic attraction 4 and the heating layer 5 can be sufficiently performed.

The thicknesses of the electrode for electrostatic attraction 4 and the heating layer 5 are not particularly limited, but are each preferably within a range from 10 to 500 μm, and particularly desirably within a range from 30 to 300 μm. When the electrode for electrostatic attraction 4 and the heating layer 5 each have a thickness within the above ranges, a material to be heated, such as a wafer, can be suitably attracted electrostatically and heated.

### Power Supply Terminal Portion

In the present invention, the power supply terminal portion 7 for supplying electricity to the heating layer 5 has a structure having a hollow portion 9 for enabling positioning of a spring terminal, in which a tip of the spring terminal 8 is inserted into the hollow portion 9 and the spring terminal is pressed against the power supply terminal portion 7. Accordingly, the possibility of misalignment of the spring terminal 8 is reduced, and thus sparks caused by the misalignment is avoided. That is, the hollow portion 9 is used for positioning to fix the spring terminal 8 and the power supply terminal portion 7.

The hollow portion 9 according to the present invention can be formed in the power supply terminal portion 7 by a method in which a depressed portion is formed in a carbon substrate and then CVD deposition is performed, or by a method in which CVD deposition is performed and a depression is finally formed by machining. Among these methods, the former method in which a depressed portion is formed in a carbon substrate and then CVD deposition is performed is preferred because this method causes lighter damages to the protective layer 6 and the insulator layer 3 due to the machining.

With respect to the shape of the hollow portion 9, from the viewpoint of allowing the tip of the spring terminal 8 to be inserted into and disposed in the hollow portion 9 and suitably fixing the power source wire to the power supply terminal portion 7, it is preferred that a ratio of an outer diameter D1/a height h1 of the hollow portion 9 is 0.1 or more and 10 or less, and more preferably 5 or less. If the ratio is more than 10, the thickness of the insulating layer in the hole tends to be thin, and the possibility of sparks generated by dielectric breakdown increases. The outer diameter D1 of the hollow portion 9 refers to the length from one side to the other of the outer boundary of the hollow portion 9 in the lateral direction, and the height h1 of the hollow portion 9 refers to the length of the hollow portion 9 in the thickness direction as shown in FIG. 1.

The heating layer 5 is preferably removed from the hollow portion 9. That is, it is preferred that the hollow portion 9 does not have the heating layer 5 (in FIG. 1, the hollow portion 9 has a nonconductive layer 10). This is because when the protruding portion of the spring terminal 8 is rubbed against the insulator layer 3, the heating layer 5 is exposed, which causes sparks. Thus, the heating layer 5 is preferably removed during patterning after the heating layer is covered.

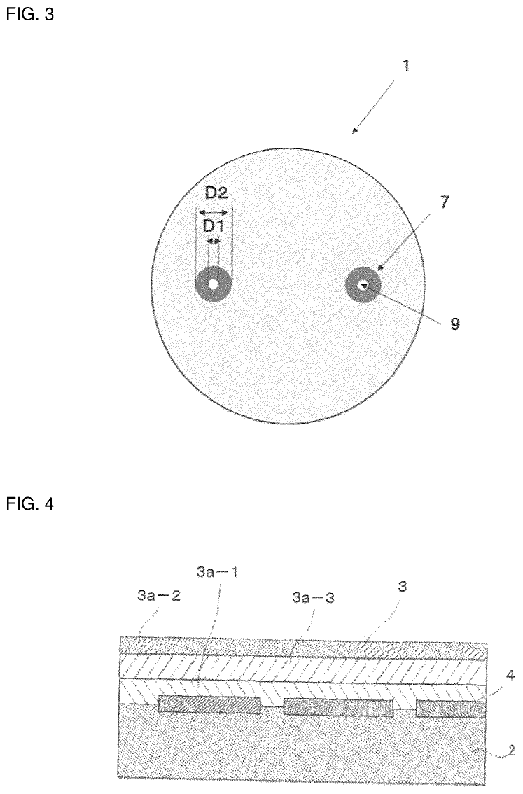

The ratio between outer diameters: an outer diameter D2 of the exposed portion of the power supply terminal portion 7 and the outer diameter D1 of the hollow portion 9, that is, D2/D1 is preferably 1.2 or more and 100 or less, and more preferably 2 or more and 10 or less. If the outer diameter D1 of the hollow portion 9 is too small for the outer diameter D2 of the exposed portion of the power supply terminal portion 7, the protruding portion of the spring terminal 8 does not suitably fit in the hollow portion 9, which causes misalignment. On the other hand, if the outer diameter D1 of the hollow portion 9 is too large for the outer diameter D2 of the exposed portion of the power supply terminal portion 7, the area of a part of the terminal portion which is in contact with a power source wire decreases, which prevents a large current from flowing. The outer diameter D2 of the exposed portion of the power supply terminal portion 7 refers to the outer diameter of the entire power supply terminal portion 7 as shown in FIG. 3.

### Spring Terminal

The spring terminal 8 is generally formed with a spring support portion 8a on a fixed side, an arc-shaped spring portion 8b, and a movable spring portion 8c as shown in FIG. 1. The movable spring portion 8c is actuated upward and downward with respect to the spring support portion 8a by elastic deformation of the arc-shaped spring portion 8b. The spring terminal 8 having a protruding tip is inserted into the hollow portion 9 of the power supply terminal portion 7 and a power source wire is pressed against the power supply terminal portion 7, and thus the power source wire is fixed to the power supply terminal portion 7 by the spring terminal 8. However, the movable spring portion 8c is not necessary. Alternatively, a structure in which the spring support portion 8a on the fixed side and the arc-shaped spring portion 8b are directly bonded to each other by welding, soldering, or the like is acceptable. The linear diameter of the arc-shaped spring portion 8 b is preferably 0.5 mm or more and 5.0 mm or less, and more preferably 0.5 mm or more and 3.0 mm or less.

A washer with plasticity, such as a carbon washer, may be disposed between the spring support portion 8a on the fixed side and the power supply terminal portion 7. Accordingly, the possibility of gap formation between the spring support portion 8a on the fixed side and the power supply terminal portion 7 is reduced, leading to suppression of sparks. The spring terminal 8 is generally formed with a die by sheet metal processing using a cutting process, a bending process, or the like, or by soldering. The spring terminal is formed with highly heat-resistant materials, such as SUS, Ni, Mo, W, and Inconel.

### Insulator Layer

The insulator layer 3 formed on the electrode for electrostatic attraction 4 and the heating layer 5 preferably has an electric resistivity of 10⁶ to 10¹⁵ Ω·cm. When the insulator layer 3 having an electric resistivity within this range is formed, the electrical resistance is suitable in a medium to high temperature range from 500 °C to 800 °C, devices are not damaged by leakage current, and sufficient electrostatic attraction force can be achieved. Such an insulator layer 3 can preferably be formed of pyrolytic boron nitride.

The thickness of the insulator layer 3 is also not particularly limited, but is preferably within a range from 50 to 500 μm, and particularly desirably within a range from 70 to 300 μm. In general, in the case where an insulator layer 3 having a thickness of from 50 to 500 μm is formed, when the surface of the electrode for electrostatic attraction 4 or the heating layer 5 for bonding is smooth, the layer is easily detached due to a difference in the coefficients of thermal expansion. However, the electrode for electrostatic attraction 4 and the heating layer 5 formed in the present invention have a strong anchor effect, and thus detachment of the insulator layer 3 is prevented even after repeated rise and drop in temperature.

Furthermore, the insulator layer 3 having the above-described thickness has a sufficient insulation ability, and has a suitable electric resistivity even in a medium to high temperature range from 500 to 800 °C, so that sufficient electrostatic attraction force can be ensured.

In the heating apparatus having electrostatic attraction function 1 having the above-described structure according to the present invention, as shown in FIG. 4, when the insulator layer 3 which covers the electrode for electrostatic attraction 4 has a portion 3a-2 facing (a portion proximate to) an attracted material having a surface resistivity ρsS that is smaller than a surface resistivity ρsE of a portion 3a-1 facing (a portion proximate to) an electrode for electrostatic attraction, no residual attraction of the wafer immediately after interruption of the applied voltage remains, and thus the material to be heated can be detached.

Furthermore, when the ratio of the surface resistivity ρsE of the portion 3a-1 facing (a portion proximate to) an electrode for electrostatic attraction to the surface resistivity ρsS of the portion 3a-2 facing (a portion proximate to) an attracted material (ρsE/ρsS) is more than 1 and 100 or less, and ρsE and ρsS are each 1×10⁸ Ω/□ or more, sufficient electrostatic attraction force can be achieved from about room temperature to an elevated temperature. In FIG. 4, 3a-3 denotes an intermediate portion of the insulator layer 3 which covers the electrode for electrostatic attraction 4.

The portion 3a-1 facing (a portion proximate to) an electrode for electrostatic attraction refers to a portion from the surface of the electrode for electrostatic attraction 4 to a position 50 μm inside (in a direction toward an attracted material) from the surface. The portion 3a-2 facing (a portion proximate to) an attracted material refers to a portion from the outer surface of the insulator layer 3 which covers the electrode for electrostatic attraction to a position 50 μm inside (in a direction toward the electrode for electrostatic attraction) from the outer surface.

The thickness of the insulator layer 3 which covers the heating layer 5 is preferably 50 to 300 μm, and particularly preferably 80 to 200 μm.

In the present invention, the surface resistivity ρsS of the portion 3a-2 facing an attracted material can be smaller than the surface resistivity ρsE of the portion 3a-1 facing an electrode for electrostatic attraction as described above. However, it is desired that ρsE and ρsS are each 1×10⁸ Ω/□ or more, preferably 1×10⁸ Ω/□ to 1×10¹⁴ Ω/□, more preferably 1×10⁹ Ω/□ to 1×10¹⁴ Ω/□, and still more preferably 1×10¹⁰ Ω/□ to 1×10¹⁴ Ω/□. Furthermore, it is desired that ρsE/ρsS is more than 1 and 100 or less, and more preferably more than 1 and 10 or less. The surface resistivity of the intermediate portion 3a-3 can be 2×10⁸ to 9×10¹⁴ Ω/□, and is preferably between ρsE and ρsS In the heating apparatus according to the present invention, at a temperature while a wafer is attracted, when the surface resistivity (Ω/□) of the insulator layer 3 in the lateral direction is denoted by A and the volume resistivity (Ω·cm) of the insulator layer 3 in the thickness direction is denoted by B, the ratio of the surface resistivity to the volume resistivity (A/B) can be 0.01 or more. When the ratio is less than 0.01, electrostatic attraction force cannot be achieved. Furthermore, in the worst case, dielectric breakdown occurs between electrodes having a double-pole structure, resulting in a problem that electrostatic attraction function cannot be exerted. It is thought that the proportion of leakage current between the electrodes having a double-pole structure passing directly through the insulator layer 3 increases, and thus leakage current to a wafer that contributes to attracting the wafer decreases, resulting in decreased electrostatic attraction force. Accordingly, when the ratio of the surface resistivity to the volume resistivity (A/B) is 0.01 or more, preferably 0.1 or more, dielectric breakdown does not occur between double-pole electrodes and practically sufficient electrostatic attraction force is achieved, and thus the above problem is solved.

The upper limit of the ratio of the surface resistivity to the volume resistivity (A/B) is not particularly limited, but is generally 100,000 or less, and particularly preferably 10,000 or less for ensuring the dielectric withstanding voltage between the electrode and the wafer.

Examples of means for changing and controlling the ratio of the surface resistivity to the volume resistivity (A/B) include adding and dispersing impurities into the insulator layer 3 to give anisotropy, carrying out annealing to give crystal orientation, and when the insulator layer 3 is formed by a vapor deposition method, changing the type of raw material gases, the reaction temperature, the reaction pressure, and the like.

### Method of Producing Heating Apparatus

The method of producing the heating apparatus having electrostatic attraction function according to the present invention is not particularly limited, but the heating apparatus can be suitably produced by a chemical vapor deposition method.

For example, when the electrode for electrostatic attraction 4 and the heating layer 5 are formed, methane gas is subjected to a reaction in a reaction chamber under conditions at 1000 to 2500 °C and 1 to 10 Torr, and boron halide is introduced into the same reaction chamber in an amount ranging from 0.001 to 30 mass % as a boron concentration to form pyrolytic graphite layers on a supporting substrate 2, which is, for example, formed of graphite and which has a protective layer 6 on its surface. Then, the pyrolytic graphite layers may be processed such that a pattern of the electrode for electrostatic attraction 4 is formed on the front side of the supporting substrate 2, and a pattern of the heating layer 5 is formed on the back side of the supporting substrate 2.

Accordingly, when the electrode for electrostatic attraction 4 and the heating layer 5, which are formed of pyrolytic graphite containing boron and/or boron carbide in an amount of from 0.001 to 30 mass % as a boron concentration, are formed by a chemical vapor deposition method, fine projections and depressions are formed on their surfaces, thus an extremely excellent anchor effect can be exerted, and detachment of the insulator layer 3 formed thereon can be effectively prevented.

The protective layer 6 and the insulator layer 3 are also preferably formed in the same manner by a chemical vapor deposition method. Each of the layers formed by a chemical vapor deposition method is of high purity, and detachment and generation of particles are suppressed. As described above, the protective layer 6 is not necessary depending on the type of the supporting substrate 2. In this case, as shown in FIG. 4, the electrode for electrostatic attraction 4 and the heating layer 5 (not shown) may be formed directly on the supporting substrate 2. Accordingly, a heating apparatus having electrostatic attraction function having such structure and including the other components which are the same as those shown in FIG. 1 can be provided.

Hereinafter, the present invention will be specifically described with reference to Examples and Comparative Examples, but the present invention is not limited thereto. The present invention is not limited to the embodiments described herein. The embodiments are presented by way of example, and those having substantially the same structure as that in the technical ideas described in the claims of the present invention and exerting similar action and effects fall within the scope of the present invention.

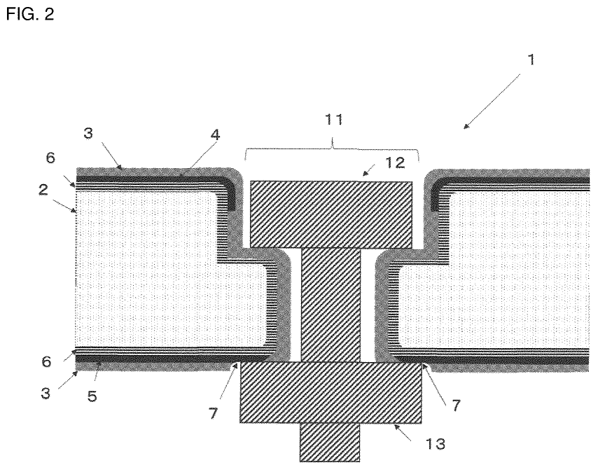

For example, the supporting substrate, as well as the shapes of the electrode for electrostatic attraction and the heating layer are not limited to those shown in FIG. 1 and FIG. 2.

### EXAMPLES

### Example 1

A graphite substrate covered with a protective layer 6 formed of pyrolytic boron nitride having a diameter of 200 mm and a thickness of 15 mm was prepared.

Next, methane gas was pyrolyzed on the protective layer 6 in a reaction chamber under conditions at 2200 °C and 5 Torr, and boron halide (boron trichloride) was introduced into the same reaction chamber in an amount ranging from 0.001 to 30 mass % as a boron concentration to form a pyrolytic graphite layer having a thickness of 100 μm in which boron and boron carbide coexisted. An electrode pattern was formed on the front side of the pyrolytic graphite layer to form an electrode for electrostatic attraction 4, and a heater pattern was formed on the back side to form a heating layer 5.

A power supply terminal portion 7 for supplying electricity to the heating layer 5 was formed so as to have a structure having no through hole 11 communicating with a wafer-mounting surface, and a hollow portion 9 for enabling positioning of a spring terminal 8 was provided in the power supply terminal portion 7 for supplying electricity to the heating layer 5. A stable electrical connection was achieved by inserting a tip of the spring terminal 8 into the hollow portion 9 and pressing the spring terminal 8 against the hollow portion 9. The ratio of an outer diameter D1/a height h1 of the hollow portion 9 was 0.5. The ratio between outer diameters, that is, the outer diameter D2 of the exposed portion of the power supply terminal portion 7 and the outer diameter D1 of the hollow portion 9 (D2/D1) was 2.0. In the hollow portion 9, the heating layer 5 was removed and did not exist.

Thereafter, ammonia, boron trichloride, and methane were reacted on these two surfaces under conditions at 1600 °C and 5 Torr to form an insulator layer 3 containing carbon-containing pyrolytic boron nitride having a thickness of 200 μm. Accordingly, a heating apparatus having electrostatic attraction function was produced. The surface resistivity (ρsS) of the portion facing an attracted material was 2.9×10⁸ (Ω/□), the volume resistivity in the thickness direction was 9.5×10⁹ (Ω·cm), and the ratio between them (surface resistivity/volume resistivity) was 11.9.

At an elevated temperature of 600 °C, a voltage of ±500 V was applied between the double-pole electrodes to attract a wafer. The temperature distribution of the wafer was measured by thermography, and no decrease in temperature due to the power supply terminal portion 7 and the hollow portion 9 for enabling positioning was observed, and excellent temperature uniformity was demonstrated.

Thereafter, in the insulator layer 3 portion of a specimen, samples for resistivity measurement were cut from both of the portion proximate to an attracted material and the portion proximate to an electrode for electrostatic attraction, and the surface resistivity was measured. Each of the samples had a thickness of 50 μm. The surface resistivity (ρsE) of the portion facing an electrode for electrostatic attraction was 3.2×10⁹(Ω/□).

The surface resistivity was measured according to a JIS standard (K6911-1995 5.13 resistivity), using a measurement device Hiresta IP MCP-HT260 available from Dia Instruments Co., Ltd. and an HRS probe as a probe. The sample for the measurement was obtained from about the center of the heating apparatus having electrostatic attraction function. The measurement was performed under atmosphere at a room temperature of 25 °C and a humidity of 50%.

### Example 2

A heating apparatus having electrostatic attraction function was produced in the same manner as in Example 1 except that the ratio of the outer diameter D1/the height h1 of the hollow portion 9 was 2.0, the ratio between outer diameters, that is, the outer diameter D2 of the exposed portion of the power supply terminal portion and the outer diameter D1 of the hollow portion 9 (D2/D1) was 5.0.

The resulting heating apparatus was tested in the same manner as in Example 1. The temperature distribution of the wafer was measured by thermography, and no decrease in temperature due to the power supply terminal portion 7 and the hollow portion 9 for enabling positioning was observed, and excellent temperature uniformity was demonstrated.

### Comparative Example 1

A heating apparatus having electrostatic attraction function was produced in the same manner as in Example 1 except that the power supply terminal portion 7 for supplying electricity to the heating layer 5 was formed so as to have a structure having a through hole 11 into which a bolt is inserted, and the power supply terminal portion 7 for supplying electricity to the heating layer was formed so as to have a structure having no hollow portion 9 for enabling positioning, in which a wire for power supply is fixed with a bolt 12 and a nut 13 in conventional manner instead of a spring terminal 8, as shown in FIG. 2.

The resulting heating apparatus was tested in the same manner as in Example 1. The temperature distribution of the wafer was measured by thermography, a decrease in temperature by 20 °C (i.e., temperature change of −20 °C) was observed at the power supply terminal portion 7 and the through hole 11, and the temperature uniformity was inferior to that in Example 1.

### Comparative Example 2

A heating apparatus having electrostatic attraction function was produced in the same manner as in Example 1 except that the ratio of the outer diameter D1/the height h1 of the hollow portion was 20.

The resulting heating apparatus was tested in the same manner as in Example 1. As a result, dielectric breakdown occurred between the inner surface of the hollow portion 9 and the protruding portion of the spring terminal due to the thinner insulating layer on the inner surface of the hollow portion 9, and the reliability was inferior to that in Example 1.

### Comparative Example 3

A heating apparatus having electrostatic attraction function was produced in the same manner as in Example 1 except that the ratio between outer diameters, that is, the outer diameter D2 of the exposed portion of the power supply terminal portion and the outer diameter D1 of the hollow portion (D2/D1) was 1.05.

The resulting heating apparatus was tested in the same manner as in Example 1. As a result, sparks were observed at the terminal portion because the contact area was too small for the current, and the reliability was inferior to that in Example 1.

### Industrial Applicability

The present invention provides a structure which has, in contrast to prior art, no through hole communicating with a wafer-mounting surface in the power supply terminal portion for supplying electricity to the heating layer, and which has, instead of the through hole, a depression for enabling positioning of a spring terminal in the power supply terminal portion for supplying electricity to the heating layer. That is, the structure has no through hole which causes a decrease in temperature of a wafer. Furthermore, the structure provides better contact between the wafer and the spring terminal, resulting in improved temperature distribution of the wafer and improved temperature uniformity.

In addition, in the present invention, the electrode for electrostatic attraction and the heating layer have an excellent anchor effect, and stronger bonding is achieved by chemical bonding between boron added to the electrode for electrostatic attraction and the heating layer and nitrogen in the protective layer and the insulator layer. Thus, problems regarding detachment of the insulator layer are avoided. Furthermore, the present invention can provide a heating apparatus having electrostatic attraction function which comprises an insulator layer having suitable electrical resistance and has sufficient electrostatic attraction force even in a medium to high temperature range from 500 to 800 °C, in which breakage of devices due to leakage current is prevented.

### REFERENCE SIGNS LIST

1 Heating apparatus having electrostatic attraction function
2 Supporting substrate
3 Insulator layer
3a-1 Portion facing electrode for electrostatic attraction in insulator layer which covers electrode for electrostatic attraction
3a-2 Portion facing attracted material in insulator layer which covers electrode for electrostatic attraction
3a-3 Intermediate portion in insulator layer which covers electrode for electrostatic attraction
4 Electrode for electrostatic attraction
5 Heating layer
6 Protective layer
7 Power supply terminal portion
8 Spring terminal
8a Spring supporting portion on fixed side
8b Arc-shaped spring portion
8c Movable spring portion
9 Hollow portion for enabling positioning of spring terminal
10 Nonconductive layer
11 Through hole
12 Bolt
13 Nut

Scopes of what is claimed:

1. A heating apparatus having electrostatic attraction function, comprising:
at least a supporting substrate;
an electrode for electrostatic attraction and a heating layer formed on the supporting substrate;
an insulator layer containing boron nitride formed on the electrode for electrostatic attraction and the heating layer; and
a power supply terminal portion for supplying electricity to the heating layer,
wherein the power supply terminal portion has a structure having no through hole communicating with a wafer-mounting surface, and
a power source wire is fixed to the power supply terminal portion with a spring terminal.

2. The heating apparatus having electrostatic attraction function according to claim 1, wherein the power supply terminal portion is provided with a hollow portion for enabling positioning of the spring terminal.

3. The heating apparatus having electrostatic attraction function according to claim 2, wherein a ratio of an outer diameter D1/a height h1 of the hollow portion is 0.1 or more and 10 or less.

4. The heating apparatus having electrostatic attraction function according to claim 2, wherein the heating layer in the hollow portion is removed.

5. The heating apparatus having electrostatic attraction function according to claim 2, wherein a ratio of an outer diameter D2 of the exposed portion of the power supply terminal portion to an outer diameter D1 of the hollow portion as the ratio of the outer diameters (D2/D1) is 1.2 or more and 100 or less.

6. The heating apparatus having electrostatic attraction function according to claim 1, wherein the power source wire is fixed to the power supply terminal portion by inserting a washer with plasticity between the power supply terminal portion and the spring terminal.

7. The heating apparatus having electrostatic attraction function according to claim 1, wherein
in the insulator layer formed on the electrode for electrostatic attraction, a ratio of a surface resistivity (ρsE) of a portion facing the electrode for electrostatic attraction to a surface resistivity (ρsS) of a portion facing an attracted material (ρsE/ρsS) is more than 1 and 100 or less, ρsE and ρsS are each 1×10⁸ Ω/□ or more, and a surface resistivity of an intermediate portion is 2×10⁸ to 9×10¹⁴ Ω/□, and wherein the insulator layer has a thickness of 50 to 300 μm.

8. The heating apparatus having electrostatic attraction function according to claim 1, wherein
in the insulator layer formed on the electrode for electrostatic attraction, when a surface resistivity (Ω/□) in a lateral direction of the insulator layer is denoted by A and a volume resistivity (Ω·cm) in a depth direction of the insulator layer is denoted by B, a ratio of a surface resistivity to a volume resistivity (A/B) is 0.01 or more and 10,000 or less, and a volume resistivity in the depth direction of the insulator layer is 10⁶ to 10¹⁵ Ω·cm.

9. The heating apparatus having electrostatic attraction function according to claim 1, wherein
the electrode for electrostatic attraction and/or the heating layer are formed of pyrolytic graphite containing boron and/or boron carbide in an amount of from 0.001 to 30 mass % as a boron concentration.

10. The heating apparatus having electrostatic attraction function according to claim 1, wherein the electrode for electrostatic attraction and/or the heating layer are formed such that a protective layer formed on the supporting substrate is sandwiched therebetween.

11. The heating apparatus having electrostatic attraction function according to claim 10, wherein the protective layer includes any one of silicon nitride, boron nitride, aluminum nitride, and pyrolytic boron nitride.

12. The heating apparatus having electrostatic attraction function according to claim 1, wherein
the supporting substrate includes any one of silicon nitride sintered body, boron nitride sintered body, mixed sintered body of boron nitride and aluminum nitride, alumina sintered body, aluminum nitride sintered body, pyrolytic boron nitride, and pyrolytic boron nitride-coated graphite as a main component.

13. The heating apparatus having electrostatic attraction function according to claim 1, wherein the insulator layer is formed such that a resistivity of the insulator layer is gradually altered in the depth direction by a chemical vapor deposition method.
